(19) United States
(12) Patent Application Publication
(10) Pub. No.: US 2008/0124879 A1
(43) Pub. Date: May 29, 2008

(54) Method for Fabricating Semiconductor Device

(76) Inventor: HYUN SOO SHIN, Seongdong-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/773,216

(22) Filed: Jul. 3, 2007

(30) Foreign Application Priority Data
Jul. 4, 2006 (KR) 10-2006-0062267

(51) Int. Cl. H01L 21/336

(52) U.S. Cl. 438/301; 257/E21.409

(57) ABSTRACT

Provided is a method for fabricating a semiconductor device. In the method, a gate oxide layer and a gate electrode is formed on a substrate, and a first dopant implanted into the substrate using the gate electrode as an ion implantation mask. An insulation layer is formed on the gate electrode and the substrate to a predetermined thickness. The insulation layer is etched to form a spacer at a side of the gate electrode. A second dopant is implanted into the substrate using the spacer as an ion implantation mask. The substrate is heat treated by spike annealing after the first dopant and/or the second dopant is implanted into the substrate.

### CROSS-REFERENCE TO RELATED APPLICATION

The present application claims the benefit under 35 U.S.C. § 119 of Korean Patent Application No. 10-2006-0062267, filed Jul. 4, 2006, which is hereby incorporated by reference in its entirety.

### BACKGROUND

With the development of small-sized and highly-integrated semiconductor devices, techniques for preventing short channel effects become more important. For example, the source/drain junction depth is made small to prevent a short channel effect.

Furthermore, as the width of a gate channel decreases, the distance between source and drain regions decreases. Therefore, when an operating voltage is applied to a semiconductor device, a leakage current can flow between the source and drain regions before the operating voltage reaches a threshold value. This deteriorates the characteristics of the semiconductor device.

FIGS. 1 to 3 are views for explaining a related art method for fabricating a semiconductor device.

Referring to FIG. 1, a gate stack is formed on a substrate 1. In detail, a gate oxide layer 2 is formed on a substrate 1. Then, a polysilicon layer 3 is deposited on the gate oxide layer 2, and a photoresist layer (not shown) having a predetermined pattern is formed on the polysilicon 3. Thereafter, the polysilicon layer 3 is reactive-ion etched using the photoresist layer as a mask to form a gate electrode.

Then, a photoresist (not shown) having a predetermined pattern is formed, and a first dopant is implanted into the substrate 1 to form shallow source/drain extension regions 5 so as to form a transistor.

Referring to FIG. 2, gate spacers 4 are formed on both sides of the gate stack formed of the gate oxide layer 2 and the polysilicon layer 3. Then, a doping operation (not shown) is performed to implant a dopant into the substrate 1 to form deep source/drain extension regions 6.

After the deep source/drain extension regions 6 are formed, a heat treatment operation 7 is performed to activate the dopant implanted into the substrate 1. The heat treatment operation 7 may be performed using a rapid thermal processing (RTP) method.

Referring to FIG. 3, the RTP may be performed by keeping a process chamber in the temperature range of 800° C. to 1000° C. for ten to fifteen seconds.

The dopant implanted into the substrate 1 can be activated by the heat treatment operation 7, and defects of the substrate 1 (e.g., a silicon wafer) caused by the dopant implantation can be removed.

However, generally, such RTP should be performed several times on a substrate doped with impurities. Furthermore, when impurity ions such as boron ions are implanted into a substrate, it is difficult to prevent transient enhanced diffusion (TED) of a p-channel metal-oxide semiconductor (PMOS) transistor caused by lateral diffusion.

Moreover, current leakage can occur even in the off mode of the transistor, thereby causing malfunctioning and misbehaviors of the transistor.

### BRIEF SUMMARY

Embodiments provide a method for fabricating a semiconductor device in which current leakage occurs minimally when a transistor is in the off mode.

In one embodiment, a method for fabricating a semiconductor device includes: forming a gate oxide layer and a gate electrode on a substrate; implanting a first dopant into the substrate using the gate electrode as an ion implantation mask; forming an insulation layer on the gate electrode and the substrate to a predetermined thickness; etching the insulation layer so as to form a spacer at a side of the gate electrode; and implanting a second dopant into the substrate using the spacer as an ion implantation mask, wherein the substrate is heat treated by spike annealing after the first dopant and/or the second dopant is implanted into the substrate.

### BRIEF DESCRIPTION OF THE DRAWINGS

FIGS. 1 to 3 are views for explaining a method for fabricating a semiconductor device according to the related art.

FIGS. 4 to 11 are views for explaining a method for fabricating a semiconductor device according to an embodiment.

FIG. 12 is a graph for explaining a spike annealing method according to an embodiment.

FIG. 13 is a graph illustrating current leakage characteristics of a semiconductor device fabricated according to an embodiment.

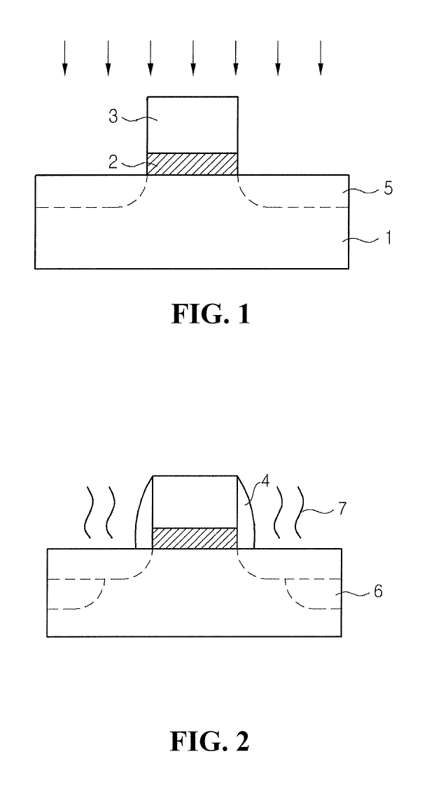

### DETAILED DESCRIPTION

Reference will now be made in detail to the embodiments of the present disclosure, examples of which are illustrated in the accompanying drawings.

In the drawings, the thicknesses of layers and regions are exaggerated for clarity, and like reference numerals denote like elements. It will also be understood that when a layer, a film, a region, or a plate is referred to as being “on” another layer, film, region, plate, or substrate, it can be directly on the other layer or substrate, or intervening layers may also be present.

FIGS. 4 to 11 are views for explaining a method for fabricating a semiconductor device according to an embodiment, and FIG. 12 is a graph for explaining a spike annealing method according to an embodiment.

Referring to FIG. 4, a gate oxide layer 110 and a gate electrode 120 are formed on a substrate 100 to form a gate stack.

Before the gate stack is formed on the substrate 100, although not shown in FIG. 4, a dopant can be implanted into an activation region of the substrate 100 by ion implantation to form a well structure, and then the substrate 100 can be heat treated to activate the dopant.

Thereafter, the gate electrode 120 can be formed by depositing a polysilicon layer on the gate oxide layer 110 and etching the polysilicon layer.

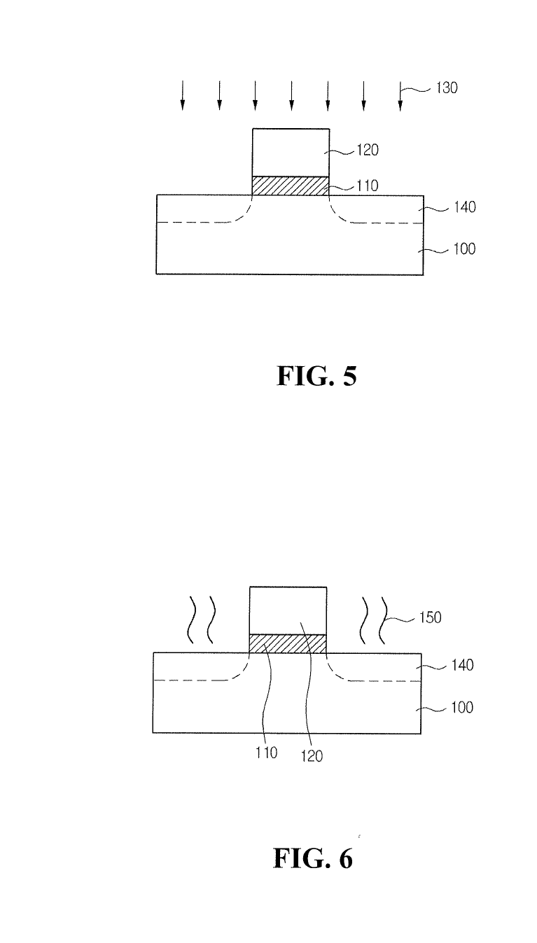

Referring to FIG. 5, a first doping operation 130 is performed on the substrate 100 using a first dopant to form a lightly doped drain (LDD) region in the substrate 100. The first doping operation 130 is performed on the entire surface of the substrate 100 using the gate stack as an ion-implantation mask.

The first dopant used for forming the LDD region can be different from a second dopant (described later) or the same as the second dopant. For example, when an n-channel metal oxide semiconductor (NMOS) transistor is formed, impurity ions such as boron ions can be implanted into a p-type substrate.

Accordingly, shallow source/drain extension regions 140 can be formed in the substrate 100.

Referring to FIG. 6, a heat treatment operation 150 is performed to activate the dopant contained in the shallow source/drain extension regions 140 of the substrate 100. The heat treatment operation 150 can be performed by spike annealing as illustrated in FIG. 12.

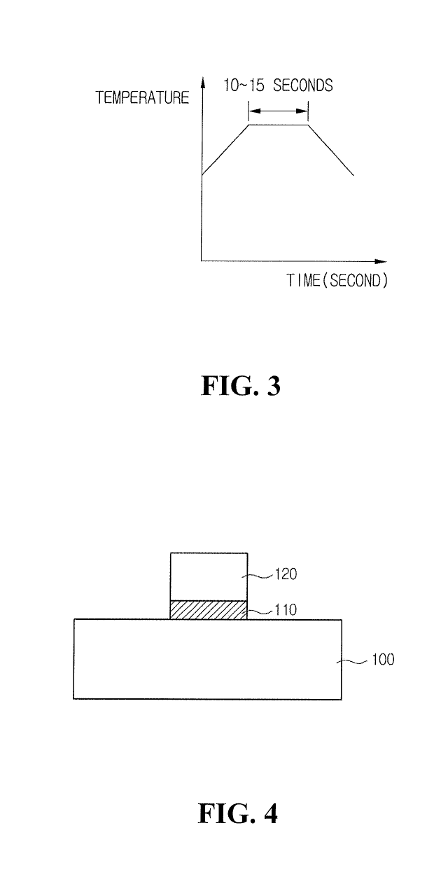

In the spike annealing, a high temperature period is relatively very short as compared with the RTP as illustrated in FIG. 3. In detail, a process chamber is kept at a high temperature only for several milliseconds, and the temperature of the process chamber increases to the high temperature more rapidly as compared with the case of the RTP.

Hereinafter, the heat treatment 150 described in reference to FIG. 6 will be referred to as a first spike annealing operation 150 for clarity.

The first spike annealing operation 150 can be performed in the temperature range of 1000° C. to 1100° C.

Although not shown in FIG. 6, an ion implantation operation can be further performed to form a pocket in a portion of the substrate 100 located under the gate oxide layer 110 in order to reduce short channel effect.

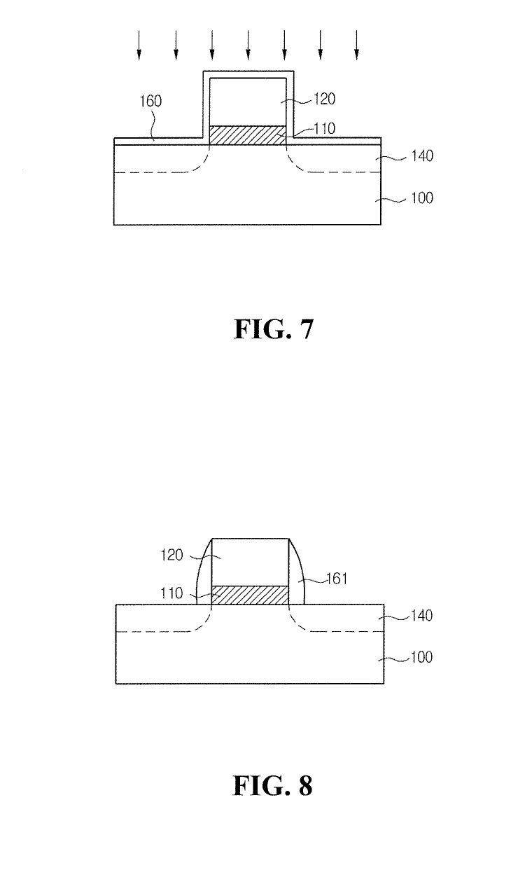

Referring to FIG. 7, after the first spike annealing operation 150, an insulation layer 160 is deposited on the substrate 100 and the gate electrode 120 to a predetermined thickness.

In an embodiment, the insulation layer 160 can be formed to a thickness of 10 Å to 40 Å.

Referring to FIG. 8, the insulation layer 160 is etched to form spacers 161 on the sides of the gate stack formed of the gate oxide layer 110 and the gate electrode 120.

The spacers 161 can be formed by depositing a silicon oxide layer or a nitride layer as the insulation layer 160 to cover the exposed substrate 100 and the gate electrode 120 and removing the insulation layer 160 by etching until the substrate 100 is exposed.

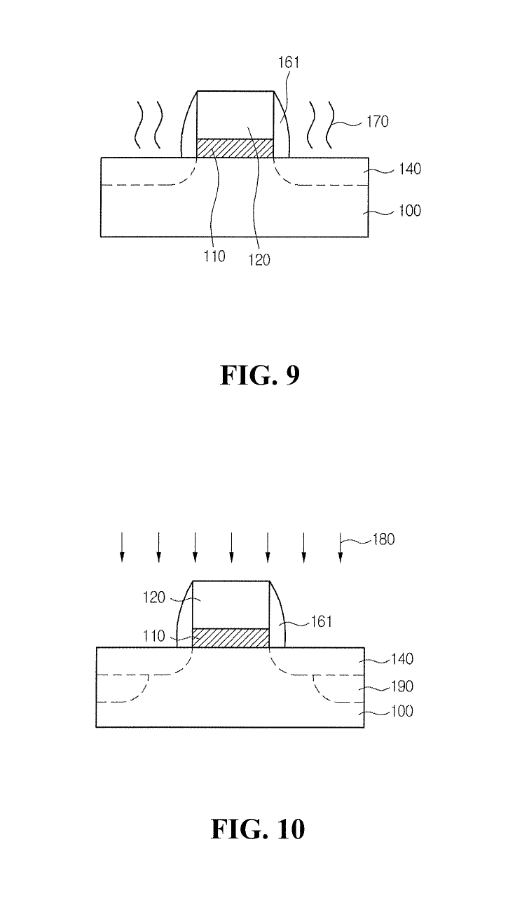

Referring to FIG. 9, a second spike annealing operation 170 can be performed to thermally stabilize the spacers 161. In the second spike annealing operation 170, a predetermined high temperature period is maintained only for several milliseconds as shown in FIG. 12, and particularly, the process chamber is kept in the temperature range of 900° C. to 1000° C. for the several milliseconds.

The second spike annealing operation 170 is performed to inhibit defects of the spacers 161 in the following operations.

Referring to FIG. 10, a second doping operation 180 is performed on the entire surface of the substrate 100 to form deep source/drain extension regions 190.

Therefore, source/drain regions with an LDD structure can be formed in the substrate 100 by the shallow source/drain extension regions 140 and the deep source/drain extension regions 190.

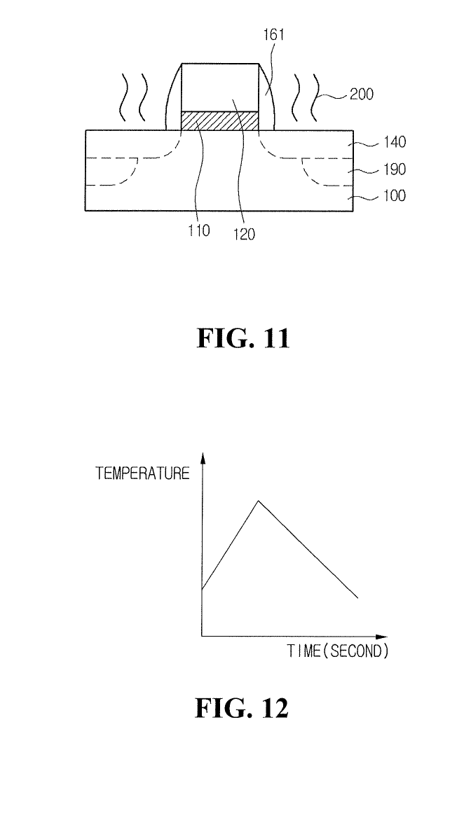

Referring to FIG. 11, after the second doping operation 180 for the LDD structure, a third spike annealing operation 200 can be performed to activate implanted ions.

The third spike annealing operation 200 is performed by keeping the process chamber in the temperature range of 1000° C. to 1150° C. for several milliseconds.

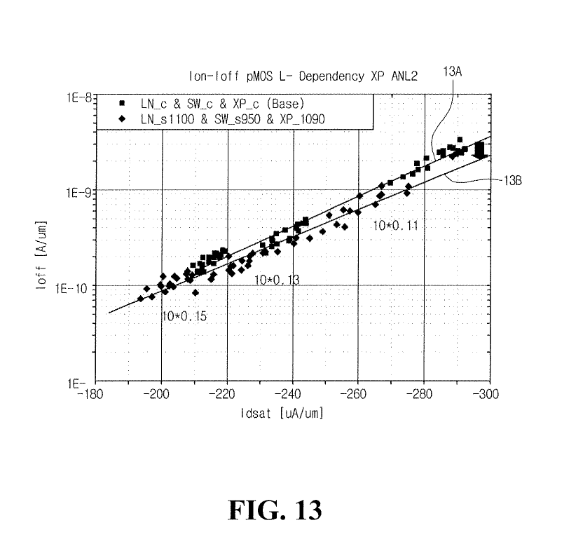

In a semiconductor device fabricated by the above-described method, the possibility of current leakage significantly reduces when a transistor is in the off mode. Experimental results for this are shown in FIG. 13.

FIG. 13 is a graph illustrating current leakage characteristics of a semiconductor device fabricated according to an embodiment.

Referring to FIG. 13, a line 13A represents current leakage characteristics of a semiconductor device fabricated according to the related art, and a line 13B represents current leakage characteristics of the semiconductor device fabricated according to an embodiment of the present invention.

A leakage current Ioff increases in linear proportion to a saturation current density Idsat. However, in transistor off mode, the leakage current of the semiconductor device according to an embodiment is less than that of the semiconductor of the related art.

As described above, according to the embodiments, current leakage can be reduced in a semiconductor device in transistor off mode.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for fabricating a semiconductor device, the method comprising:
forming a gate oxide layer and a gate electrode on a substrate;
implanting a first dopant into the substrate using the gate electrode as an ion implantation mask;
forming a spacer on sidewalls of the gate electrode;
implanting a second dopant into the substrate using the spacer as an ion implantation mask; and
heat treating the substrate by spike annealing after implanting the first dopant into the substrate, after implanting the second dopant into the substrate, or after both implanting the first dopant into the substrate and implanting the second dopant into the substrate.

2. The method according to claim 1, wherein heat treating the substrate by spike annealing comprises performing a first spike annealing in a temperature range of 1000° C. to 1100° C. after implanting the first dopant into the substrate.

3. The method according to claim 1, wherein heat treating the substrate by spike annealing comprises performing a third spike annealing in a temperature range of 1000° C. to 1150° C. after implanting the second dopant into the substrate.

4. The method according to claim 1, further comprising performing a second spike annealing in a temperature range of 900° C. to 1000° C. after forming the spacer.

5. The method according to claim 1, wherein the first dopant and the second dopant comprise the same dopant.

6. A method for fabricating a semiconductor device, the method comprising:
implanting a dopant into a substrate on which a gate electrode is formed so as to form a shallow source/drain extension region;
forming a spacer on sidewalls of the gate electrode;
implanting the dopant into the substrate so as to form a deep source/drain extension region; and
heat treating the substrate by spike annealing at a predetermined temperature for several milliseconds so as to activate the dopant implanted into the substrate after forming the shallow source/drain extension region and/or forming the deep source/drain extension region.

7. The method according to claim 6, wherein the predetermined temperature is in a temperature range of 1000° C. to 1100° C.

8. The method according to claim 6, further comprising performing spike annealing in a temperature range of 900° C. to 1000° C. for several milliseconds after forming the spacer.
